(19) United States
(12) Patent Application Publication
(10) Pub. No.: US 2024/0407152 A1
(43) Pub. Date: Dec. 5, 2024

(54) GATE STRUCTURES AND SEMICONDUCTOR DEVICES INCLUDING THE GATE STRUCTURES

(71) Applicant: SAMSUNG ELECTRONICS CO., LTD., Suwon-si (KR)

(72) Inventors: Eulji JEONG, Suwon-si (KR); Sukhoon KIM, Suwon-si (KR); Hyojung NOH, Suwon-si (KR); Sungnam LYU, Suwon-si (KR); Byounghoon LEE, Suwon-si (KR)

(21) Appl. No.: 18/642,174

(22) Filed: Apr. 22, 2024

(30) Foreign Application Priority Data
Jun. 5, 2023 (KR) 10-2023-0072082

(51) Int. Cl. H10B 12/00

(52) U.S. Cl. CPC H10B 12/34; H10B 12/053; H10B 12/315

(57) ABSTRACT

A gate structure comprising: a first conductive pattern; a first seed pattern on a lower surface and a first portion of a sidewall of the first conductive pattern, wherein the first seed pattern includes a first material, and the first conductive pattern includes a second material that is different from the first material; and a gate insulation pattern that is in contact with a second portion of the sidewall of the first conductive pattern and the first seed pattern, wherein the first material has a first work function, and the second material has a second work function, and wherein the first work function is lower than the second work function.

### CROSS-REFERENCE TO RELATED APPLICATIONS

This application claims priority under 35 U.S.C. § 119 to Korean Patent Application No. 10-2023-0072082 filed on Jun. 5, 2023 in the Korean Intellectual Property Office, the disclosure of which is hereby incorporated by reference in its entirety.

### TECHNICAL FIELD

Example embodiments of the present disclosure relate to gate structures and semiconductor devices including the gate structures.

### DESCRIPTION OF RELATED ART

In a DRAM device, as the size of the gate electrode decreases, a method of reducing the resistance of the gate electrode may be needed. In order to reduce the resistance, the gate electrode may include a material having a low (lower) resistivity, however, the material with the low (lower) resistivity may have a low (lower) effective work function, so the gate electrode with such material may not satisfy the requirement of the flat band voltage.

### SUMMARY OF THE INVENTION

Example embodiments of the present inventive concepts provide a gate structure having improved characteristics.

Example embodiments of the present inventive concepts provide semiconductor devices including a gate structure having improved characteristics.

According to example embodiments of the inventive concepts, there is provided a gate structure. The gate structure may include a first conductive pattern; a first seed pattern on a lower surface and a first portion of a sidewall of the first conductive pattern, wherein the first seed pattern includes a first material, and the first conductive pattern includes a second material that is different from the first material; and a gate insulation pattern that is in contact with a second portion of the sidewall of the first conductive pattern and the first seed pattern, wherein the first material has a first work function, and the second material has a second work function, and wherein the first work function is lower than the second work function.

According to example embodiments of the inventive concepts, there is provided a gate structure. The gate structure may include a first conductive pattern; a first seed pattern on a lower surface and a portion of a sidewall of the first conductive pattern, wherein the first seed pattern includes a first material, and the first conductive pattern includes a second material that is different from the first material; a second conductive pattern that is in contact with an upper surface of the first conductive pattern and an uppermost surface of the first seed pattern; and a gate insulation pattern that is in contact with a sidewall of the second conductive pattern and a sidewall of the first seed pattern, wherein the first material has a first work function, and the second material has a second work function, and wherein the first work function is lower than the second work function.

According to example embodiments of the inventive concepts, there is provided a semiconductor device. The semiconductor device may include an active pattern on a substrate; a gate structure in an upper portion of the active pattern; a bit line structure on a central portion of the active pattern; a contact plug structure on each of opposite edge portions of the active pattern in a horizontal direction that is parallel with an upper surface of the substrate; and a capacitor on the contact plug structure, wherein the gate structure includes: a first conductive pattern; a first seed pattern on a lower surface and a first portion of a sidewall of the first conductive pattern, wherein the first seed pattern includes a first material, and the first conductive pattern includes a second material that is different from the first material; and a gate insulation pattern that is in contact with a second portion of the sidewall of the first conductive pattern and the first seed pattern, wherein the first material has a first work function, and the second material has a second work function, and wherein the first work function is lower than the second work function.

The gate structure in accordance with example embodiments may have a low resistance and a low flat band voltage, thus may have an improved (e.g., enhanced) on-off characteristic.

### BRIEF DESCRIPTION OF THE DRAWINGS

FIG. 1 is a cross-sectional view illustrating a first gate structure in accordance with example embodiments.

FIGS. 2 and 3 are cross-sectional views illustrating a method of forming the first gate structure in accordance with example embodiments.

FIG. 4 is a cross-sectional view illustrating a second gate structure in accordance with example embodiments.

FIG. 5 is a cross-sectional view illustrating a third gate structure in accordance with example embodiments.

FIG. 6 is a cross-sectional view illustrating a fourth gate structure in accordance with example embodiments.

FIG. 7 is a plan view illustrating a semiconductor device in accordance with example embodiments.

FIG. 8 is a cross-sectional view taken along line A-A′ of FIG. 7.

FIG. 9 is a cross-sectional view taken along line B-B′ of FIG. 7.

FIGS. 10 to 26 are plan views and cross-sectional views illustrating a method of manufacturing a semiconductor device in accordance with example embodiments.

### DETAILED DESCRIPTION

The above and other aspects and features of a gate structure, a method of forming the gate structure, a semiconductor device including the gate structure, and a method of manufacturing the semiconductor device in accordance with example embodiments will be more fully described by detailed descriptions that follow, with reference to the accompanying drawings. It will be understood that, although the terms “first,” “second,” and/or “third” may be used herein to describe various materials, layers (films), regions, electrodes, pads, patterns, structures and processes, these materials, layers (films), regions, electrodes, pads, patterns, structures and processes should not be limited by these terms. These terms are only used to distinguish one material, layer (film), region, electrode, pad, pattern, structure and process from another material, layer (film), region, electrode, pad, pattern, structure and process. Thus, a first material, layer (film), region, electrode, pad, pattern, structure and process discussed below could be termed a second or third material, layer (film), region, electrode, pad, pattern, structure and process without departing from the teachings of inventive concepts.

FIG. 1 is a cross-sectional view illustrating a first gate structure in accordance with example embodiments.

Referring to FIG. 1, a first gate structure 90 may be (buried) in a first substrate 10 (e.g., an upper portion of the first substrate 10). The first gate structure 90 may include a first gate electrode 100 and a gate mask 80 sequentially stacked in a vertical direction that is (substantially) perpendicular to an upper surface of the first substrate 10. The first gate structure 90 may further include a gate insulation pattern 35 on (e.g., covering) sidewalls of the first gate electrode 100 and/or the gate mask 80. For example, the gate insulation pattern 35 may overlap the sidewalls of the first gate electrode 100 and/or the gate mask 80 in a horizontal direction that is (substantially parallel with the upper surface of the first substrate 10. As used herein, the term “and/or” includes any and all combinations of one or more of the associated listed items. Expressions such as “at least one of,” when preceding a list of elements, modify the entire list of elements and do not modify the individual elements of the list. As used herein, “an element A overlapping an element B in a direction X” (or similar language) means that there is at least one line that extends in the direction X and intersects both the elements A and B.

The first substrate 10 may include, for example, silicon, germanium, silicon-germanium, and/or a III-V group compound semiconductor, such as GaP, GaAs, and/or GaSb. In example embodiments, the first substrate 10 may be a silicon-on-insulator (SOI) substrate or a germanium-on-insulator (GOI) substrate.

The first gate electrode 100 may include a first seed pattern 40 and first and second conductive patterns 60 and 70. In some embodiments, the first seed pattern 40, the first conductive pattern 60, and the second conductive pattern 70 may be sequentially stacked in the vertical direction.

In example embodiments, the first conductive pattern 60 may include, for example, a metal having a low (e.g., lower, less, or smaller) resistivity such as molybdenum, tungsten, etc. For example, a resistivity of a material in the first conductive pattern 60 may be lower than a resistivity of a material in the first seed pattern 40.

In example embodiments, the first conductive pattern 60 may include an upper portion and a lower portion. The first seed pattern 40 may be on (e.g., may cover) a lower surface and a portion of a sidewall of the first conductive pattern 60 (e.g., a lower surface and a portion of a sidewall of the lower portion of the first conductive pattern 60). The lower portion of the first conductive pattern 60 may overlap with the first seed pattern 40 in the horizontal direction. For example, the first seed pattern 40 may extend around the lower portion of the first conductive pattern 60. The upper portion of the first conductive pattern 60 may not overlap with the first seed pattern 40 in the horizontal direction. That is, the first seed pattern 40 may include an upper surface contacting a lower surface and a sidewall of the lower portion of the first conductive pattern 60. The first seed pattern 40 may have a lower surface aligned with a sidewall of the upper portion of the first conductive pattern 60. An uppermost surface of the first seed pattern 40 between the upper and lower surfaces of the first seed pattern 40 may contact (an edge of) a lower surface of the upper portion of the first conductive pattern 60. In some embodiments, (the lower surface and the sidewall of) the lower portion of the first conductive pattern 60 may be spaced apart from the gate insulation pattern 35 by the first seed pattern 40. On the other hand, (the sidewall of) the upper portion of the first conductive pattern 60 may be in direct contact with the gate insulation pattern 35. The lower portion and the upper portion of the first conductive pattern 60 may form a unitary structure. A unitary structure herein may refer to a structure without a visible boundary between two sub-elements thereof. Also, it will be understood that when an element or layer is referred to as being “connected to”, “coupled to”, or “contacted to” another element or layer, it may be directly on, connected to, coupled to, or contacted to the other element or layer, or one or more intervening elements or layers may be present. In contrast, when an element is referred to as being “directly coupled,” “directly connected,” or “directly responsive” to, “directly on,” or “directly contacted to” another element, there are no intervening elements present. In addition, “electrical connection” conceptually includes a physical connection and a physical disconnection.

In example embodiments, the first seed pattern 40 may include a material having a work function lower (less or smaller) than that of the first conductive pattern 60.

The first seed pattern 40 may include, for example, a metal (e.g., tantalum), an alloy (e.g., tantalum titanium), a metal nitride (e.g., titanium nitride, tantalum nitride, lanthanum nitride, etc.), a metal silicon nitride (e.g., titanium silicon nitride, tantalum silicon nitride, etc.), and/or a metal oxide (e.g., lanthanum oxide, aluminum oxide, scandium oxide, etc.). In some embodiments, the first seed pattern 40 may include a compound of molybdenum and at least one of the above materials.

The first seed pattern 40 may have a thickness of about 0.1 Å to about 50 Å, but is not limited thereto.

The second conductive pattern 70 may be on (e.g., may contact) an upper surface of the first conductive pattern 60.

In an example embodiment, the second conductive pattern 70 may include polysilicon doped with n-type impurities or p-type impurities. In some embodiments, the second conductive pattern 70 may include a conductive material having a work function lower (less or smaller) than that of the first conductive pattern 60. The conductive material of the second conductive pattern 70 may include, for example, a metal, an alloy, a metal nitride, a metal silicon nitride, etc. For example, the second conductive pattern 70 may include a material included in the first seed pattern 40, however, the inventive concept may not be limited thereto.

The gate mask 80 may be on (e.g., may contact) an upper surface of the second conductive pattern 70. The gate mask 80 may include an insulating material. For example, the gate mask 80 may include an insulting nitride (e.g., silicon nitride) or an oxide (e.g., silicon oxide).

The gate insulation pattern 35 may contact a lower surface of the first seed pattern 40, a sidewall of the upper portion of the first conductive pattern 60, a sidewall of the second conductive pattern 70, and a sidewall of the gate mask 80.

The gate insulation pattern 35 may include, for example, silicon oxide or a metal oxide.

In the first gate electrode 100 included in the first gate structure 90, a material in the first conductive pattern 60 may have a relatively small (e.g., less, lower, or smaller) resistivity (compared with that of the first seed pattern 40 and/or that of the second conductive pattern 70), but a relatively high (e.g., higher or greater) work function (compared with that of the first seed pattern 40 and/or that of the second conductive pattern 70). The first seed pattern 40 on (e.g., covering or overlapping in the horizontal direction) the lower surface and the lower sidewall of the first conductive pattern 60 (e.g., the sidewall of the lower portion of the first conductive pattern 60) and having a relatively thin (e.g., thinner) thickness (compared with that of the first conductive pattern 60) may have a relatively low (e.g., lower, less, or smaller) work function (compared with that of the first conductive pattern 60).

Thus, the first gate electrode 100 including the first conductive pattern 60 and the first seed pattern 40 may have a low (e.g., less, lower, or smaller) resistance and a low (e.g., less, lower, or smaller) work function, and the first gate structure 90 including the first gate electrode 100 may have a low flat band voltage. As a result, an on-off characteristic of the first gate structure 90 may be improved (enhanced).

The first gate electrode 100 may further include the second conductive pattern 70 on the first conductive pattern 60, as the second conductive pattern 70 includes doped polysilicon or a material having a relatively low (e.g., less, lower, or smaller) work function (compared with that of the first conductive pattern 60), a leakage current from the first gate electrode 100 to the first substrate 10 may be reduced.

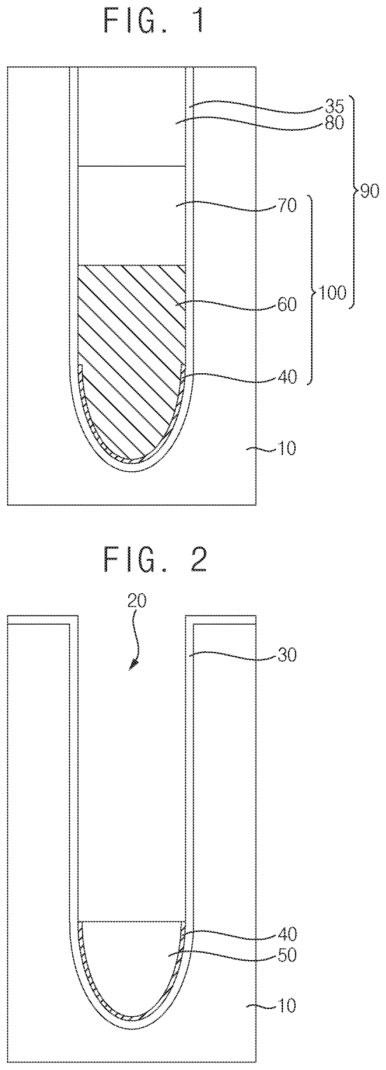

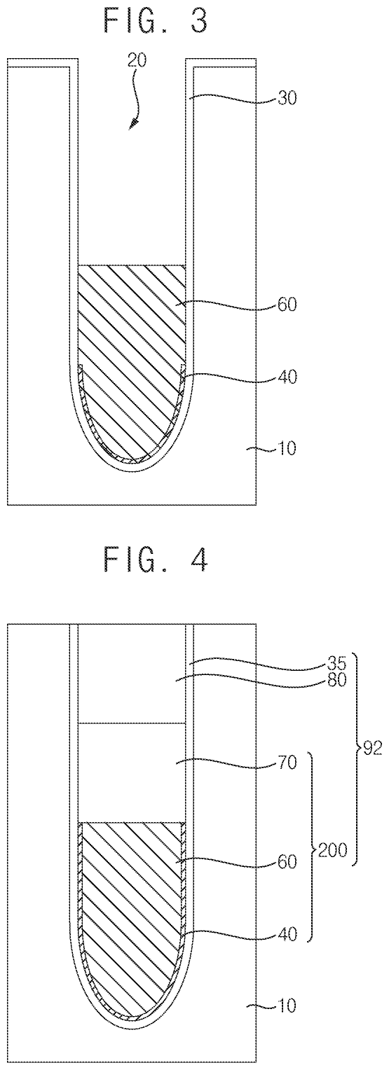

FIGS. 2 and 3 are cross-sectional views illustrating a method of forming the first gate structure 90 in accordance with example embodiments.

Referring to FIG. 2, an upper portion of the first substrate 10 may be removed to form a trench 20, and a gate insulation layer 30 may be formed on an inner wall of the trench 20 and an upper surface of the first substrate 10.

A first seed layer may be formed on the gate insulation layer 30, a first sacrificial layer may be formed on the first seed layer to fill the trench 20, and an upper portion of the first sacrificial layer may be removed, and thus a first sacrificial pattern 50 may be formed in (at least) a lower portion of the trench 20.

In example embodiments, the first seed layer may be formed by an atomic layer deposition (ALD) process, and may be conformally formed on the gate insulation layer 30. The first seed layer may include a material having a low work function (e.g., a work function lower than that of the first conductive pattern 60 to be formed by the following processes). The first seed layer may have a thickness of (about) 0.1 Å to (about) 50 Å, but is not limited thereto.

The first sacrificial pattern 50 may include, for example, spin-on-hardmask (SOH), amorphous carbon layer (ACL), etc.

A portion of the first seed layer not covered by the first sacrificial pattern 50 may be removed to form a first seed pattern 40. In example embodiments, the uppermost surface of the first seed pattern 40 may be substantially coplanar with an upper surface of the first sacrificial pattern 50.

Referring to FIG. 3, the first sacrificial pattern 50 may be removed by, for example, an ashing process and/or a stripping process to expose the first seed pattern 40.

A first conductive pattern 60 may be formed on the first seed pattern 40 to fill the lower portion of the trench 20. In example embodiments, the first conductive pattern 60 may be formed by a bottom-up growth process from the first seed pattern 40, and may include a metal, for example, molybdenum.

As the first conductive pattern 60 is formed by the bottom-up growth process, no void or seam may be formed in the first conductive pattern 60, and the first conductive pattern 60 may have a large grain size. Additionally, the first conductive pattern 60 may not be formed on the gate insulation layer 30 except for a portion of the gate insulation layer 30 adjacent to the first seed pattern 40. For example, the first conductive pattern 60 may not be formed on the gate insulation layer 30 in the middle portion and upper portion of the trench 20.

In example embodiments, an upper surface of the first conductive pattern 60 may be higher (e.g., higher vertical level) than an upper surface of the first seed pattern 40. A farther distance from the lower surface of the first substrate 10 may be a higher vertical level. A closer distance from the lower surface of the first substrate 10 may be a lower vertical level.

Referring back to FIG. 1, a second conductive layer may be formed on the first conductive pattern 60 and the gate insulation layer 30 to fill a remaining portion of the trench 20 (e.g., the middle portion and upper portion of the trench 20), and an upper portion of the second conductive layer (in the upper portion of the trench 20) may be removed by, for example, an etch back process, and thus a second conductive pattern 70 may be formed in the middle portion of the trench 20. The middle portion of the trench 20 may be located between the lower portion and the upper portion of the trench 20 in the vertical direction.

A gate mask layer may be formed on the second conductive pattern 70 and the gate insulation layer 30 to fill a remaining portion of the trench 20 (e.g., the upper portion of the trench 20), and a planarization process may be performed on the gate mask layer and an upper portion of the gate insulation layer 30 until the upper surface of the first substrate 10 is exposed.

Thus, a gate mask 80 may be formed in the upper portion of the trench 20, and the gate insulation layer 30 may be transformed into a gate insulation pattern 35 on the inner wall of the trench 20. The first seed pattern 40, the first conductive pattern 60, and the second conductive pattern 70 may collectively form the first gate electrode 100. The gate insulation pattern 35, the first seed pattern 40, the first conductive pattern 60, the second conductive pattern 70 and the gate mask 80 in the trench 20 may collectively form a first gate structure 90.

As illustrated above, the first seed pattern 40 may be formed in the trench 20, and the first conductive pattern 60 may be formed by the bottom-up growth process from the first seed pattern 40, and thus no void or seam may be formed in the first conductive pattern 60.

FIG. 4 is a cross-sectional view illustrating a second gate structure 92 in accordance with example embodiments. The second gate structure 92 may be substantially the same as or similar to the first gate structure 90 shown in FIG. 1, except for some elements, and thus repeated explanations may be omitted herein.

Referring to FIG. 4, a second gate structure 92 may include a second gate electrode 200 instead of the first gate electrode 100, and the first seed pattern 40 included in the second gate electrode 200 may be on (e.g., cover) not only the lower surface and the lower sidewall of the first conductive pattern 60 but also an upper sidewall of the first conductive pattern 60. For example, the first seed pattern 40 may overlap with the (entire) sidewall of the first conductive pattern 60 in the horizontal direction.

Thus, the first conductive pattern 60 may not directly contact the gate insulation pattern 35, and the first seed pattern 40 having a low work function may contact the gate insulation pattern 35. For example, the first conductive pattern 60 may be spaced apart from the gate insulation pattern 35 by the first seed pattern 40. As a result, the second gate electrode 200 including the first seed pattern 40 and the first conductive pattern 60 may have a low work function, and the second gate structure 92 including the second gate electrode 200 may have a low flat band voltage.

The second conductive pattern 70 may be on (e.g., (directly) contact) the upper surface of the first conductive pattern 60 and an uppermost surface of the first seed pattern 40.

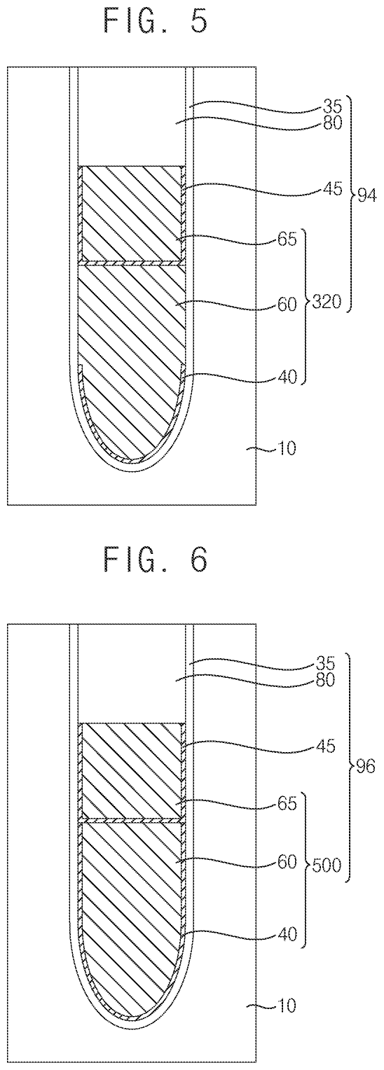

FIG. 5 is a cross-sectional view illustrating a third gate structure 94 in accordance with example embodiments. The third gate structure 94 may be substantially the same as or similar to the first gate structure 90 shown in FIG. 1, except for some elements, and thus repeated explanations may be omitted herein.

Referring to FIG. 5, the third gate structure 94 may include a third gate electrode 320, instead of the first gate electrode 100, and the third gate electrode 320 may include a third conductive pattern 65 and a second seed pattern 45 that is on (e.g., covers) a lower surface and a sidewall of the third conductive pattern 65, instead of the second conductive pattern 70 in FIG. 1.

Thus, (a lower surface of) the second seed pattern 45 may (directly) contact the upper surface of the first conductive pattern 60. For example, the third conductive pattern 65 may be spaced apart from the gate insulation pattern 35 and the first conductive pattern 60 by the second seed pattern 45.

In example embodiments, the third conductive pattern 65 may include, for example, a metal having a low (e.g., lower, less, or smaller) resistivity, and the second seed pattern 45 may include a material having a work function lower than that of the third conductive pattern 65. For example, a resistivity of a material in the third conductive pattern 65 may be lower than a resistivity of a material in the second seed pattern 45. Thus, the third conductive pattern 65 may include a metal, for example, molybdenum, tungsten, etc., and the second seed pattern 45 may include, for example, a metal, an alloy, a metal nitride, a metal silicon nitride, a metal oxide, or a compound of molybdenum and at least one of the above materials.

The second seed pattern 45 may have a thickness of (about) 0.1 Å to (about) 50 Å, but is not limited thereto.

As the third gate electrode 320 further includes the third conductive pattern 65 having a relatively low (e.g., lower, less, or smaller) resistivity (compared with the second seed pattern 45) and the second seed pattern 45 having a relatively low (e.g., lower, less, or smaller) work function (compared with the third conductive pattern 65), in addition to the first seed pattern 40 and the first conductive pattern 60, the third gate structure 94 may have a low resistance and a low flat band voltage.

FIG. 6 is a cross-sectional view illustrating a fourth gate structure 96 in accordance with example embodiments. The fourth gate structure 96 may be substantially the same as or similar to the third gate structure 94 shown in FIG. 5, except for some elements, and thus repeated explanations may be omitted herein.

Referring to FIG. 6, a fourth gate structure 96 may include a fourth gate electrode 500, instead of the third gate electrode 320, and the first seed pattern 40 included in the fourth gate electrode 500 may be on (e.g., cover) not only the lower surface and the lower sidewall of the first conductive pattern 60 but also an upper sidewall of the first conductive pattern 60. For example, the first seed pattern 40 may overlap with the (entire) sidewall of the first conductive pattern 60 in the horizontal direction.

Thus, an uppermost surface of the first seed pattern 40 may (directly) contact a lower surface of the second seed pattern 45. In an example embodiment, the first and second seed patterns 40 and 45 may include substantially the same material, and thus may be merged with each other. The first and second seed patterns 40 and 45 may form a unitary structure. Alternatively, the first and second seed patterns 40 and 45 may include different materials from each other, and thus may be differentiated from each other. The first conductive pattern 60 may be spaced apart from the gate insulation pattern 35 by the first seed pattern 40 and spaced apart from the third conductive pattern 65 by the second seed pattern 45.

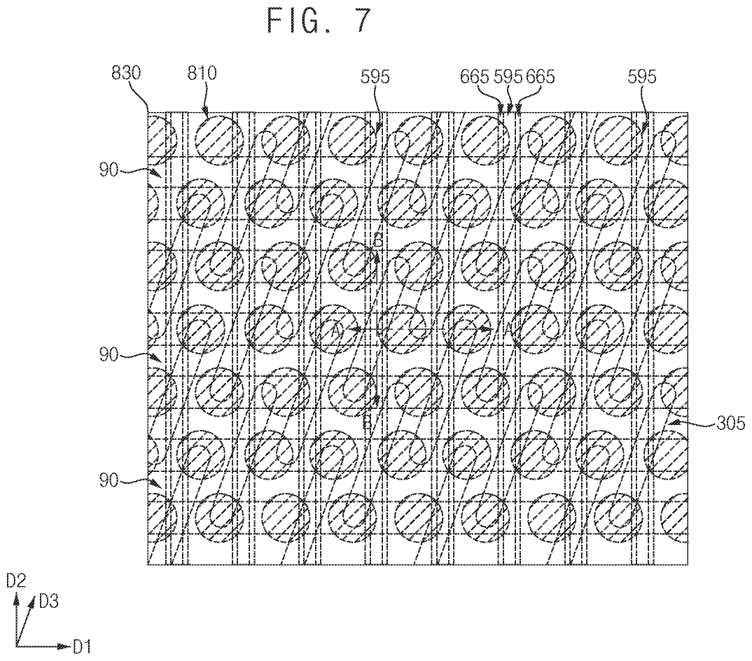

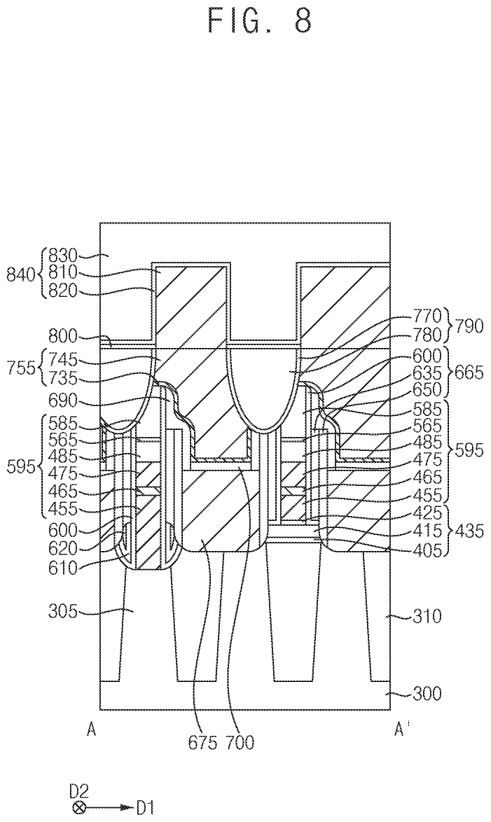

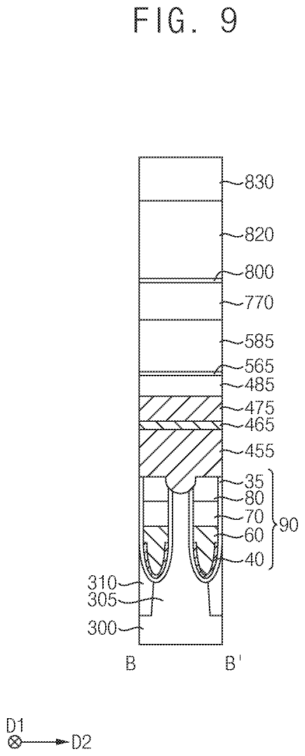

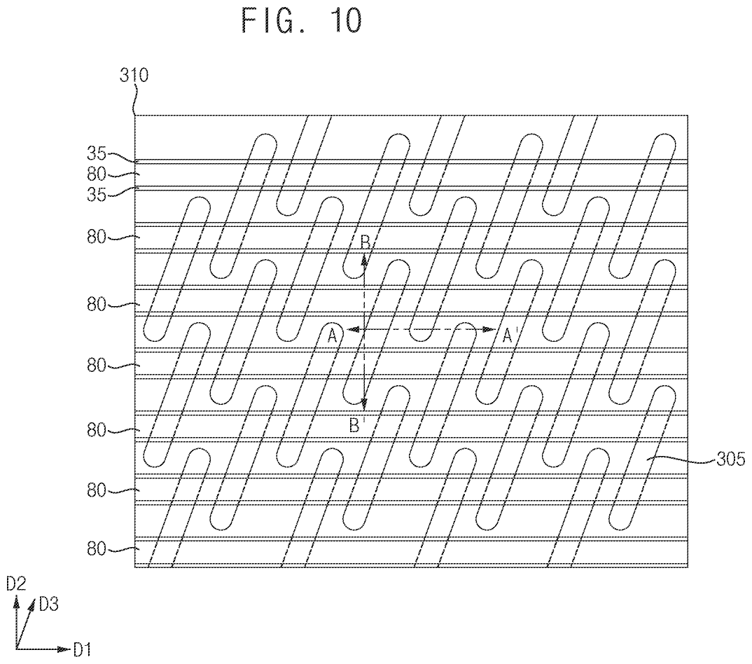

FIG. 7 is a plan view illustrating a semiconductor device in accordance with example embodiments, FIG. 8 is a cross-sectional view taken along line A-A′ of FIG. 7, and FIG. 9 is a cross-sectional view taken along line B-B′ of FIG. 7.

This semiconductor device may be a DRAM device to which the first gate structure 90 of FIG. 1 is applied, and thus repeated explanations on the first gate structure 90 may be omitted herein. However, this semiconductor device may include one of the second, third, and fourth gate structures 92, 94, and 96 illustrated with reference to FIGS. 4, 5, and 6, respectively, instead of the first gate structure 90.

Hereinafter, two directions among horizontal directions that are substantially parallel to an upper surface of a second substrate 300, which may be substantially perpendicular to each other, may be referred to as first and second directions D1 and D2, and a direction among the horizontal directions, which may have an acute angle with respect to the first and second directions D1 and D2, may be referred to as a third direction D3. A direction substantially perpendicular to the upper surface of the second substrate 300 may be referred to as a vertical direction.

Referring to FIGS. 7 to 9, the semiconductor device may include an active pattern 305, a first gate structure 90, a bit line structure 595, a contact plug structure, and a capacitor 840 on the second substrate 300.

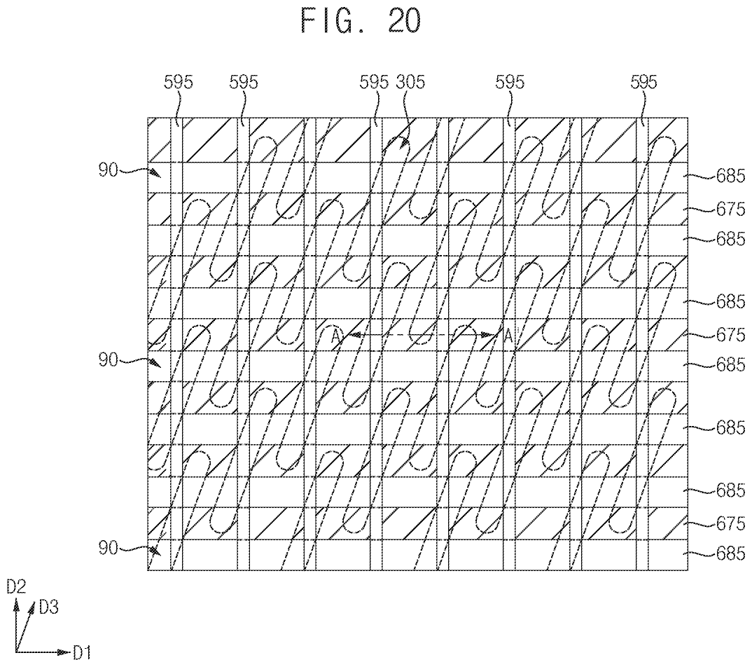

Additionally, the semiconductor device may further include an isolation pattern 310, a spacer structure 665, a fourth spacer 690, a fence pattern 685 (refer to FIG. 20), first and second insulation pattern structures 435 and 790, fourth and fifth insulation patterns 610 and 620, a metal silicide pattern 700 and a second etch stop layer 800.

The active pattern 305 may extend in the third direction D3 on the second substrate 300, and a plurality of active patterns 305 may be spaced apart from each other in the first and second directions D1 and D2. A sidewall of the active pattern 305 may be (at least partially) covered by the isolation pattern 310. The active pattern 305 may include a material substantially the same as a material of the second substrate 300, and the isolation pattern 310 may include, for example, an oxide such as silicon oxide.

The first gate structure 90 may be formed in a second recess in (e.g., extending through) upper portions of the active pattern 305 and the isolation pattern 310 in the first direction D1. The first gate structure 90 may extend in the first direction D1, and a plurality of first gate structures 90 may be spaced apart from each other in the second direction D2.

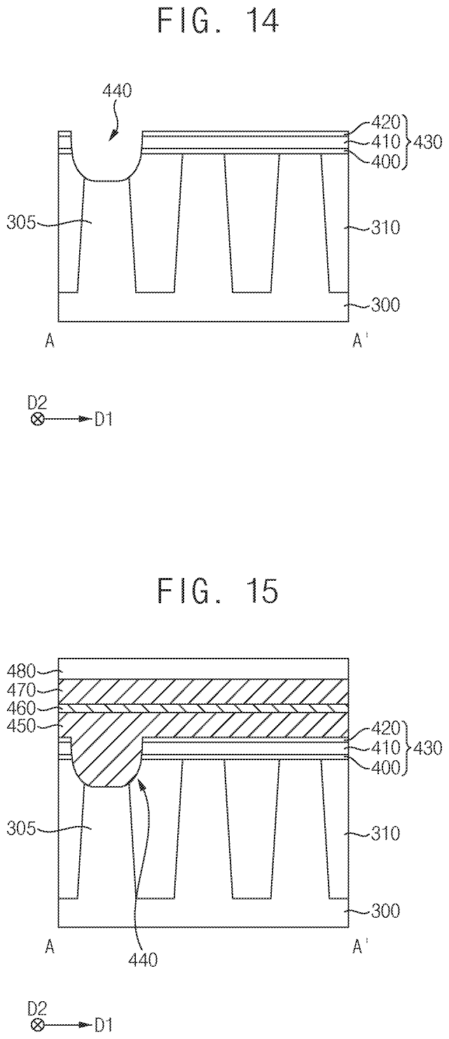

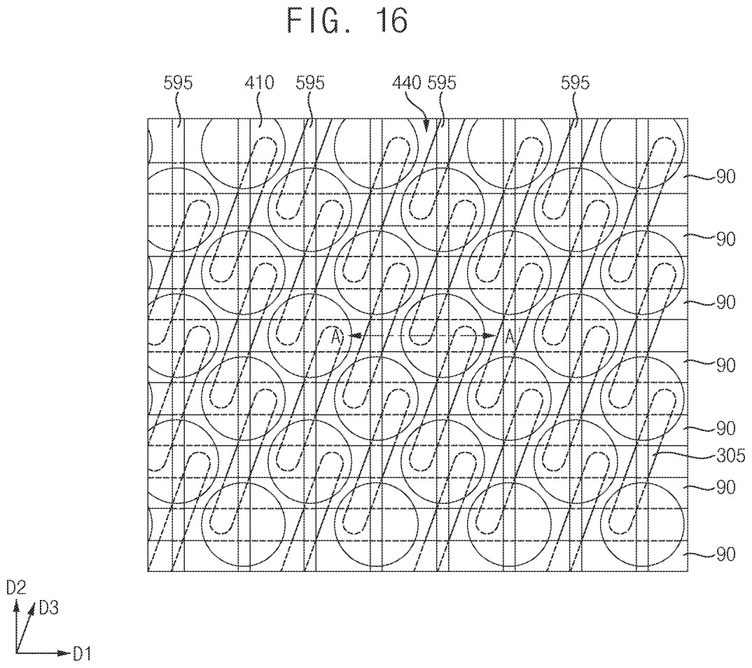

Referring to FIGS. 7, 8, and 9 together with FIGS. 13 and 14, a first opening 440 may be formed in (e.g., extending through) the first insulation layer structure 430 to expose upper portions (e.g., upper surfaces) of the active pattern 305, the isolation pattern 310 and the gate mask 80 of the first gate structure 90, and an upper surface of a central portion in the third direction D3 of the active pattern 305 may be exposed by the first opening 440.

In example embodiments, an area of a bottom of the first opening 440 may be greater than an area of the upper surface of the active pattern 305 exposed by the first opening 440. Thus, the first opening 440 may also expose an upper surface of a portion of the isolation pattern 310 adjacent to the active pattern 305. Additionally, the first opening 440 may be in (e.g., may extend through) an upper portion of the active pattern 305 and an upper portion of the isolation pattern 310 adjacent thereto, and thus the bottom of the first opening 440 may be lower than an upper surface of a portion of the active pattern 305 where the first opening 440 is not formed, that is, an upper surface of each of opposite edge portions in the third direction D3 of the active pattern 305.

The bit line structure 595 may include a fourth conductive pattern 455, a first barrier pattern 465, a fifth conductive pattern 475, a first mask 485, a first etch stop pattern 565 and a capping pattern 585 sequentially stacked in the vertical direction on the first opening 440 or on the first insulation pattern structure 435. The fourth conductive pattern 455, the first barrier pattern 465, and the fifth conductive pattern 475 may collectively form a conductive structure, and the first mask 485, the first etch stop pattern 565, and the capping pattern 585 may collectively form an insulation structure.

The fourth conductive pattern 455 may include, for example, doped polysilicon, the first barrier pattern 465 may include, for example, a metal nitride such as titanium nitride, or a metal silicon nitride such as titanium silicon nitride, the fifth conductive pattern 475 may include, for example, a metal such as tungsten, and each of the first mask 485, the first etch stop pattern 565, and the capping pattern 585 may include, for example, an insulating nitride such as silicon nitride.

In example embodiments, the bit line structure 595 may extend in the second direction D2 on the second substrate 300, and a plurality of bit line structures 595 may be spaced apart from each other in the first direction D1.

The fourth and fifth insulation patterns 610 and 620 may be formed on (in) the first opening 440, and may be on (e.g., may contact) a lower sidewall of the bit line structure 595. The fourth insulation pattern 610 may include, for example, an oxide such as silicon oxide, and the fifth insulation pattern 620 may include, for example, an insulating nitride such as silicon nitride.

The first insulation pattern structure 435 may be formed under the bit line structure 595 on the active pattern 305 and the isolation pattern 310. For example, the first insulation pattern structure 435 may be between the bit line structure 595 and the active pattern 305 and between the bit line structure and the isolation pattern 310 in the vertical direction. The first insulation pattern structure 435 may include first, second, and third insulation patterns 405, 415, and 425 sequentially stacked in the vertical direction. The first and third insulation patterns 405 and 425 may include, for example, an oxide such as silicon oxide, and the second insulation pattern 415 may include, for example, an insulating nitride such as silicon nitride.

The contact plug structure may include a lower contact plug 675, a metal silicide pattern 700, and an upper contact plug 755 sequentially stacked on the active pattern 305 and the isolation pattern 310 in the vertical direction.

The lower contact plug 675 may (directly) contact the upper surface of each of opposite edge portions in the third direction D3 of the active pattern 305. In example embodiments, a plurality of lower contact plugs 675 may be spaced apart from each other in the second direction D2 between neighboring (adjacent) ones of the bit line structures 595 in the first direction D1, and the fence pattern 685 may be formed between neighboring (adjacent) ones of the lower contact plugs 675 in the second direction D2. The fence pattern 685 may include, for example, an insulating nitride such as silicon nitride.

The lower contact plug 675 may include, for example, doped polysilicon, and the metal silicide pattern 700 may include, for example, titanium silicide, cobalt silicide, nickel silicide, etc.

The upper contact plug 755 may include a second metal pattern 745 and a second barrier pattern 735 on (covering) a lower surface of the second metal pattern 745. The second metal pattern 745 may include, for example, a metal such as tungsten, and the second barrier pattern 735 may include, for example, a metal nitride such as titanium nitride.

In example embodiments, a plurality of upper contact plugs 755 may be spaced apart from each other in the first and second directions D1 and D2, and may be arranged in a honeycomb pattern or a lattice pattern in a plan view. Each of the upper contact plugs 755 may have a shape of, for example, a circle, an ellipse or a polygon in a plan view. However, the shape and arrangement of the upper contact plugs 755 in a plan view are not limited thereto.

The spacer structure 665 may include a first spacer 600 on (e.g., covering) a sidewall of the bit line structure 595 and a sidewall of the third insulation pattern 425, an air spacer 635 on (e.g., covering) a lower outer sidewall of the first spacer 600, and a third spacer 650 on (e.g., covering) an outer sidewall of the air spacer 635, a sidewall of the first insulation pattern structure 435, and upper surfaces of the fourth and fifth insulation patterns 610 and 620.

Each of the first and third spacers 600 and 650 may include, for example, an insulating nitride such as silicon nitride, and the air spacer 635 may include air. For example, the air spacer 635 may include an empty space or a space filled with air or gas.

The fourth spacer 690 may be formed on an outer sidewall of a portion of the first spacer 600 on an upper sidewall of the bit line structure 595, and may be on (e.g., may cover) a top of the air spacer 635 and an upper surface of the third spacer 650. The fourth spacer 690 may include, for example, an insulating nitride such as silicon nitride.

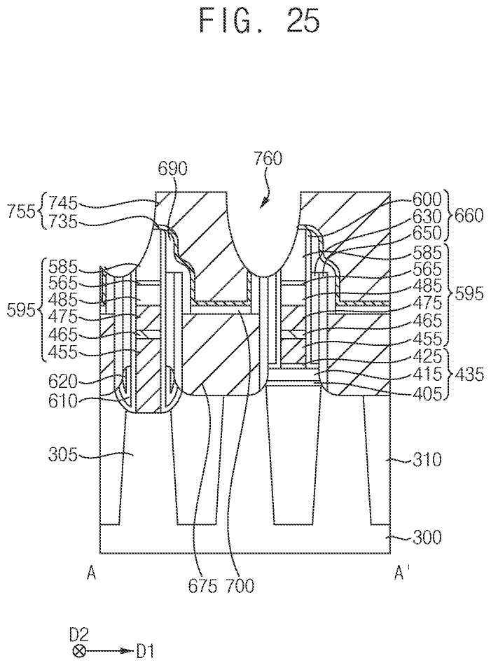

Referring to FIGS. 7 and 8 together with FIGS. 24 and 25, the second insulation pattern structure 790 may include a sixth insulation pattern 770 and a seventh insulation pattern 780. The sixth insulation pattern 770 may be formed on an inner wall of a sixth opening 760 in (e.g., extending through) the upper contact plug 755, a portion of the insulation structure included in the bit line structure 595, and portions of the first, third, and fourth spacers 600, 650, and 690 to extend around (e.g., surround) the upper contact plug 755 in a plan view. The seventh insulation pattern 780 may be formed on the sixth insulation pattern 770, and may fill a remaining portion of the sixth opening 760. The top of the air spacer 635 may be closed by the sixth insulation pattern 770.

The sixth and seventh insulation patterns 770 and 780 may include, for example, an insulating nitride such as silicon nitride.

The second etch stop layer 800 may be formed on the sixth and seventh insulation patterns 770 and 780, the upper contact plug 755, and the fence pattern 685. The lower electrode 810 included in the capacitor 840 may extend in (e.g., extend through) the second etch stop layer 800 to (directly) contact an upper surface of the upper contact plug 755.

The semiconductor device may include the first gate structure 90, and as the first gate structure 90 has a low resistance, a low flat band voltage, and an improved (enhanced) on-off characteristic, the semiconductor device including the first gate structure 90 may have improved (enhanced) electrical characteristics.

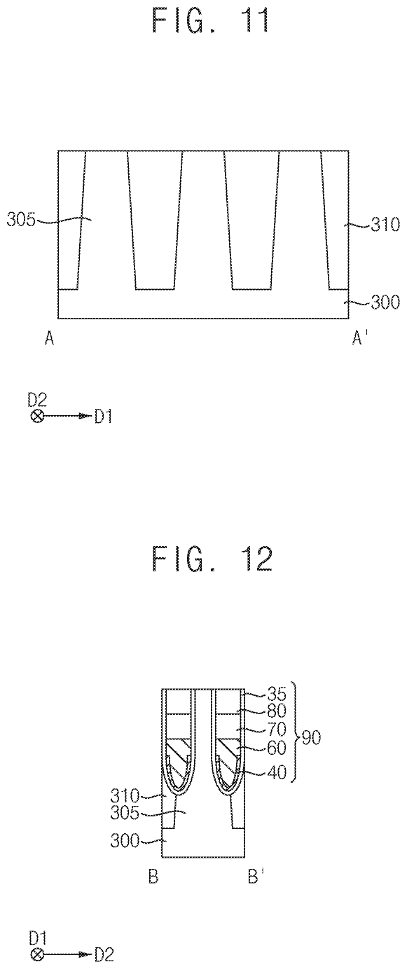

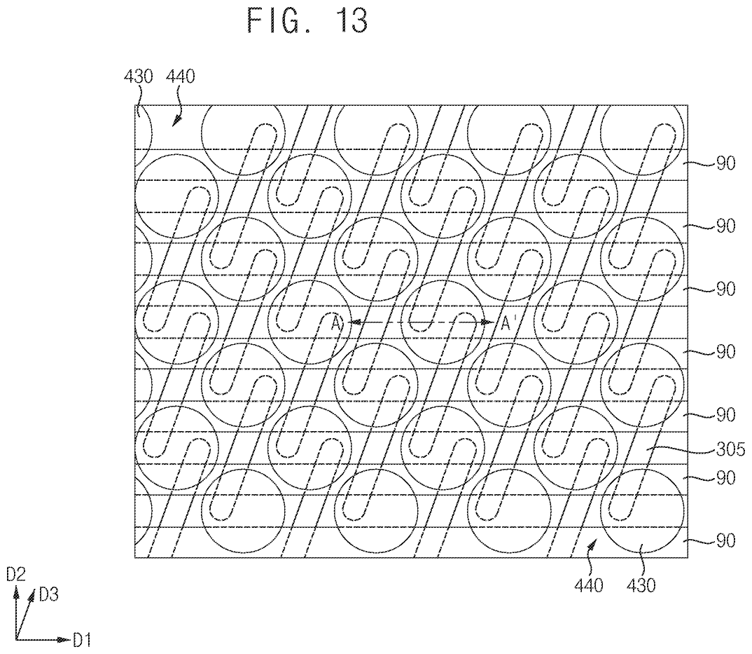

FIGS. 10 to 26 are plan views and cross-sectional views illustrating a method of manufacturing a semiconductor device in accordance with example embodiments. Particularly, FIGS. 10, 13, 16, 20 and 24 are the plan views, FIGS. 11, 14-15, 17-19, 21-23 and 25-26 are cross-sectional views taken along lines A-A′ of corresponding plan views, respectively, and FIG. 12 is a cross-sectional view taken along line B-B′ of FIG. 10.

This method may be an application of the method of forming the first gate structure 90 illustrated with reference to FIGS. 1 to 3 to a method of manufacturing a DRAM device, and repeated explanations may be omitted herein.

Referring to FIGS. 10 to 12, an upper portion of a second substrate 300 may be removed to form a first recess, and an isolation pattern 310 may be formed in the first recess.

As the first recess is formed in (on) the second substrate 300, an active pattern 305 may be defined in (on) the second substrate 300, and a sidewall of the active pattern 305 may be covered by the isolation pattern 310. A plurality of the active patterns 305 may be spaced apart from each other by the isolation pattern 310.

The active pattern 305 and the isolation pattern 310 may be partially etched to form a second recess extending in the first direction D1, and a first gate structure 90 may be formed in the second recess. In example embodiments, the first gate structure 90 may extend in the first direction D1, and a plurality of first gate structures 90 may be spaced apart from each other in the second direction D2.

Referring to FIGS. 13 and 14, a first insulation layer structure 430 may be formed on the active pattern 305, the isolation pattern 310, and the first gate structure 90. The first insulation layer structure 430 may include first, second, and third insulation layers 400, 410, and 420 sequentially stacked.

The first insulation layer structure 430 may be patterned, and the active pattern 305, the isolation pattern 310, and upper portions of the gate mask 80 and the gate insulation pattern 35 of the first gate structure 90 may be partially etched by an etching process using the patterned first insulation layer structure 430 as an etching mask to form a first opening 440. In example embodiments, the first insulation layer structure 430 remaining after the etching process may have a shape of, for example, a circle or an ellipse in a plan view, and a plurality of first insulation layer structures 430 may be spaced apart from each other in the first and second directions D1 and D2. Each of the first insulation layer structures 430 may overlap edge portions in the third direction D3 of neighboring (adjacent) active patterns 305, respectively.

Referring to FIG. 15, a fourth conductive layer 450, a first barrier layer 460, a fifth conductive layer 470, and a first mask layer 480 may be sequentially stacked on the first insulation layer structure 430, and the active pattern 305, the isolation pattern 310 and the first gate structure 90 exposed by the first opening 440, which may collectively form a conductive layer structure. The fourth conductive layer 450 may (at least partially) fill the first opening 440.

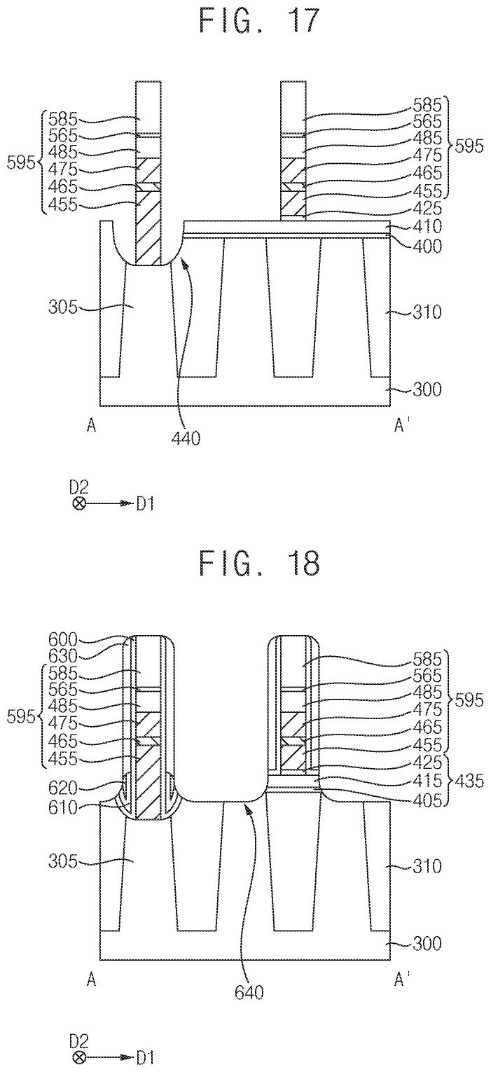

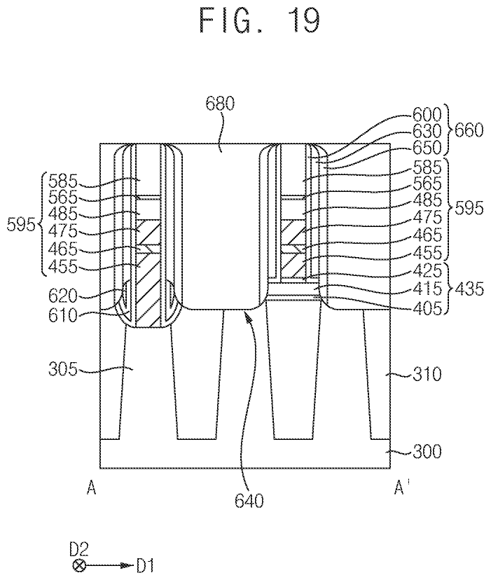

Referring to FIGS. 16 and 17, a first etch stop layer and a capping layer may be sequentially stacked on the conductive layer structure, and the capping layer may be etched to form a capping pattern 585.

The first etch stop layer, the first mask layer 480, the fifth conductive layer 470, the first barrier layer 460 and the fourth conductive layer 450 may be sequentially etched by an etching process using the capping pattern 585 as an etching mask.

In example embodiments, the capping pattern 585 may extend in the second direction D2, and a plurality of capping patterns 585 may be spaced apart from each other in the first direction D1.

By the etching process, a fourth conductive pattern 455, a first barrier pattern 465, a fifth conductive pattern 475, a first mask 485, a first etch stop pattern 565, and the capping pattern 585 may be sequentially stacked on the first opening 440, and a third insulation pattern 425, the fourth conductive pattern 455, the first barrier pattern 465, the fifth conductive pattern 475, the first mask 485, the first etch stop pattern 565, and the capping pattern 585 may be sequentially stacked on the second insulation layer 410 of the first insulation layer structure 430 at an outside of the first opening 440.

Hereinafter, the fourth conductive pattern 455, the first barrier pattern 465, the fifth conductive pattern 475, the first mask 485, the first etch stop pattern 565 and the capping pattern 585 sequentially stacked may be referred to as a bit line structure 595. The fourth conductive pattern 455, the first barrier pattern 465, and the fifth conductive pattern 475 may collectively form a conductive structure, and the first mask 485, the first etch stop pattern 565, and the capping pattern 585 may collectively form an insulation structure. In example embodiments, the bit line structure 595 may extend in the second direction D2 on the second substrate 300, and a plurality of bit line structures 595 may be spaced apart from each other in the first direction D1.

Referring to FIG. 18, a first spacer layer may be formed on the second substrate 300 having the bit line structure 595, and fourth and fifth insulation layers may be sequentially formed on the first spacer layer.

The first spacer layer may be on (e.g., may cover) a sidewall of the third insulation pattern 425 under a portion of the bit line structure 595 on the second insulation layer 410, and the fourth and fifth insulation layers may fill a remaining portion of the first opening 440.

The fourth and fifth insulation layers may be etched by an etching process. In example embodiments, the etching process may be performed by a wet etching process using an etching solution such as H₂PO₃, SCl, HF, etc., and portions of the fourth and fifth insulation layers at the outside of the first opening 440 may be removed. Thus, a portion of the first spacer layer at the outside of the first opening 440 may be exposed, and portions of the fourth and fifth insulation layers in the first opening 440 may form fourth and fifth insulation patterns 610 and 620, respectively.

A second spacer layer may be formed on the exposed portion of the first spacer layer and the fourth and fifth insulation patterns 610 and 620 in the first opening 440, and may be anisotropically etched to form a second spacer 630 on the exposed portion of the first spacer layer and the fourth and fifth insulation patterns 610 and 620 to cover a sidewall of the bit line structure 595.

A dry etching process may be performed using the capping pattern 585 and the second spacer 630 as an etching mask to form a second opening 640 exposing an upper surface of the active pattern 305, and upper surfaces of the isolation pattern 310. The gate mask 80 may also be exposed by the second opening 640.

By the dry etching process, a portion of the first spacer layer on the capping pattern 585 and the second insulation layer 410 may be removed, and thus a first spacer 600 on (e.g., covering) a sidewall of the bit line structure 595 may be formed. Additionally, by the dry etching process, the first and second insulation layers 400 and 410 may also be partially etched so that first and second insulation patterns 405 and 415 may remain under the bit line structure 595. The first, second, and third insulation patterns 405, 415, and 425 sequentially stacked under the bit line structure 595 may collectively form a first insulation pattern structure 435.

Referring to FIG. 19, a third spacer layer may be formed on an upper surface of the capping pattern 585, an outer sidewall of the second spacer 630, upper surfaces of the fourth and fifth insulation patterns 610 and 620, and the upper surfaces of the active pattern 305, the isolation pattern 310, the gate mask 80, and the gate insulation pattern 35 exposed by the second opening 640, and may be anisotropically etched to form a third spacer 650 on the sidewall of the bit line structure 595.

The first, second, and third spacers 600, 630, and 650 sequentially stacked on the sidewall of the bit line structure 595 may collectively form a preliminary spacer structure 660.

A second sacrificial layer may be formed on the second substrate 300 to fill the second opening 640, and may be planarized until the upper surface of the capping pattern 585 is exposed to form a second sacrificial pattern 680 in the second opening 640.

In example embodiments, the second sacrificial pattern 680 may extend in the second direction D2, and a plurality of second sacrificial patterns 680 may be spaced apart from each other in the first direction D1 by the bit line structures 595. The second sacrificial pattern 680 may include, for example, an oxide such as silicon oxide.

Referring to FIGS. 20 and 21, a second mask including a plurality of third openings, each of which may extend in the first direction D1, spaced apart from each other in the second direction D2 may be formed on the capping pattern 585, the second sacrificial pattern 680, and the preliminary spacer structure 660, and the second sacrificial pattern 680 may be etched by an etching process using the second mask as an etching mask.

In example embodiments, each of the third openings may overlap in the vertical direction an area between the first gate structures 90. By the etching process, a fourth opening exposing upper surfaces of the active pattern 305 and the isolation pattern 310 may be formed between the bit line structures 595.

After removing the second mask, a lower contact plug layer may be formed to fill the fourth opening, and may be planarized until upper surfaces of the capping pattern 585, the second sacrificial pattern 680 and the preliminary spacer structure 660 are exposed. Thus, the lower contact plug layer may be divided into a plurality of lower contact plugs 675 spaced apart from each other in the second direction D2 between the bit line structures 595. Additionally, the second sacrificial pattern 680 extending in the second direction D2 between the bit line structures 595 may be divided into a plurality of parts spaced apart from each other in the second direction D2 by the lower contact plugs 675.

The second sacrificial pattern 680 may be removed to form a fifth opening, and a fence pattern 685 may be formed in the fifth opening. In example embodiments, the fence pattern 685 may overlap the first gate structure 90 in the vertical direction.

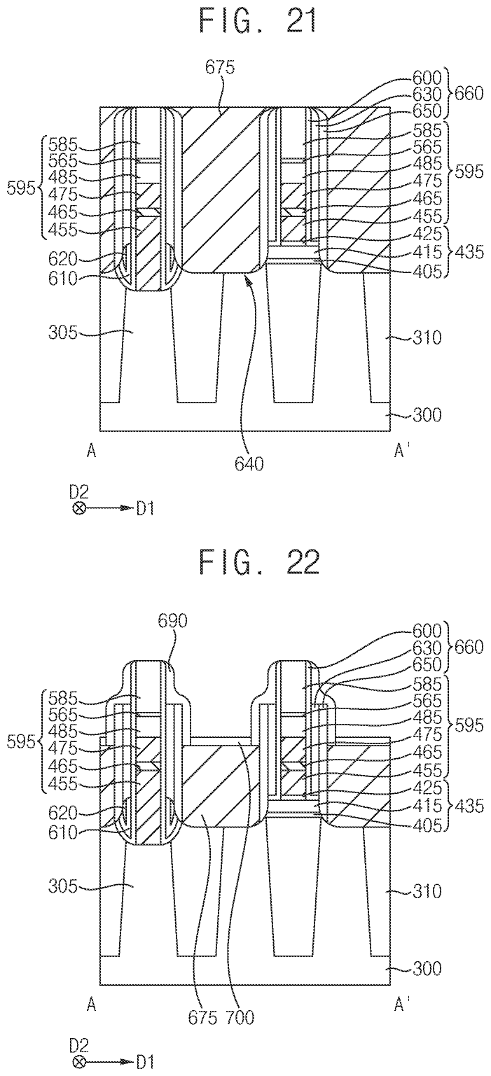

Referring to FIG. 22, an upper portion of the lower contact plug 675 may be removed to expose an upper portion of the preliminary spacer structure 660 on the sidewall of the bit line structure 595, and upper portions of the second and third spacers 630 and 650 of the preliminary spacer structure 660 may be removed.

An upper portion of the lower contact plug 675 may be further removed. Thus, an upper surface of the lower contact plug 675 may be lower than upper surfaces of the second and third spacers 630 and 650.

A fourth spacer layer may be formed on the bit line structure 595, the preliminary spacer structure 660, the fence pattern 685, and the lower contact plug 675, and may be anisotropically etched to form a fourth spacer 690 on (e.g., covering) an upper portion of the preliminary spacer structure 660 that is on each of opposite sidewalls in the first direction D1 of the bit line structure 595, and thus an upper surface of the lower contact plug 675 may be exposed.

A metal silicide pattern 700 may be formed on the upper surface of the lower contact plug 675. In example embodiments, the metal silicide pattern 700 may be formed by forming a first metal layer on the capping pattern 585, the fence pattern 685, the fourth spacer 690, and the lower contact plug 675, performing a heat treatment process, and removing an unreacted portion of the first metal layer.

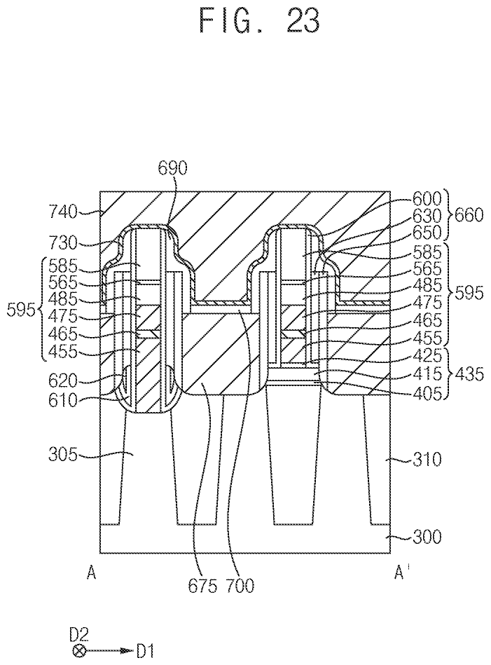

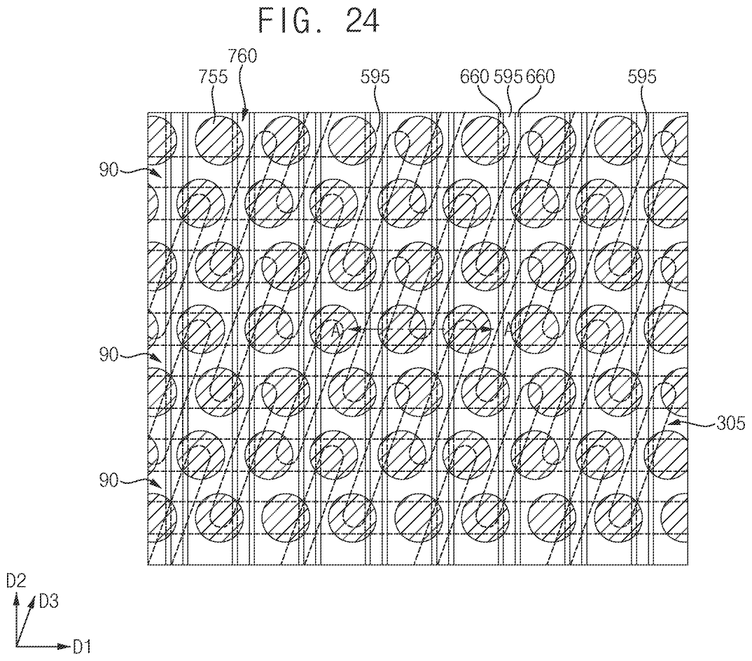

Referring to FIG. 23, a second barrier layer 730 may be formed on the capping pattern 585, the fence pattern 685, the fourth spacer 690, the metal silicide pattern 700, and the lower contact plug 675, and a second metal layer 740 may be formed on the second barrier layer 730 to fill a space between the bit line structures 595.

A planarization process may be further performed on an upper portion of the second metal layer 740. The planarization process may include a CMP process and/or an etch back process.

Referring to FIGS. 24 and 25, the second metal layer 740 and the second barrier layer 730 may be patterned to form an upper contact plug 755, and a sixth opening 760 may be formed between the upper contact plugs 755.

The sixth opening 760 may be formed by partially removing the capping pattern 585, the fence pattern 685, the preliminary spacer structure 660, and the fourth spacer 690 as well as the second metal layer 740 and the second barrier layer 730.

The upper contact plug 755 may include a second metal pattern 745 and a second barrier pattern 735 on (e.g., covering) a lower surface of the second metal pattern 745. In example embodiments, the upper contact plug 755 may have a shape of, for example, a circle, an ellipse, a polygon, a polygon with rounded corners, etc., and may be arranged, for example, in a honeycomb pattern in the first and second directions D1 and D2.

The lower contact plug 675, the metal silicide pattern 700, and the upper contact plug 755 sequentially stacked may collectively form a contact plug structure.

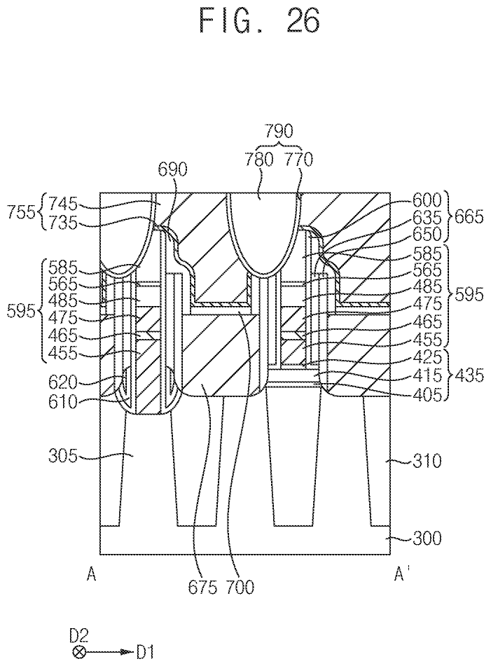

Referring to FIG. 26, the second spacer 630 included in the preliminary spacer structure 660 exposed by the sixth opening 760 may be removed to form an air gap, a sixth insulation pattern 770 may be formed on a bottom and a sidewall of the sixth opening 760, and a seventh insulation pattern 780 may be formed to fill a remaining portion of the sixth opening 760.

The sixth and seventh insulation patterns 770 and 780 may collectively form a second insulation pattern structure 790.

A top of the air gap may be covered by the sixth insulation pattern 770, and thus an air spacer 635 may be formed. The first spacer 600, the air spacer 635 and the third spacer 650 may collectively form a spacer structure 665.

Referring to FIGS. 7 to 9 again, a second etch stop layer 800 and a mold layer may be sequentially formed on the upper contact plug 755 and the second insulation pattern structure 790, the mold layer and the second etch stop layer 800 may be partially removed to form a seventh opening exposing an upper surface of the upper contact plug 755, and a lower electrode 810 may be formed in the seventh opening.

The mold layer may be removed, a dielectric layer 820 may be formed on a surface of the lower electrode 810, and an upper electrode 830 may be formed on the dielectric layer 820 to form a capacitor 840.

Upper wirings may be further formed for the fabrication of the semiconductor device.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept.

What is claimed is:

1. A gate structure comprising:
a first conductive pattern;
a first seed pattern on a lower surface and a first portion of a sidewall of the first conductive pattern, wherein the first seed pattern includes a first material, and the first conductive pattern includes a second material that is different from the first material; and
a gate insulation pattern that is in contact with a second portion of the sidewall of the first conductive pattern and the first seed pattern,
wherein the first material has a first work function, and the second material has a second work function, and
wherein the first work function is lower than the second work function.

2. The gate structure according to claim 1, wherein a lower surface of the first seed pattern is aligned with the second portion of the sidewall of the first conductive pattern.

3. The gate structure according to claim 1, wherein the second material includes molybdenum, and
wherein the first material includes tantalum, tantalum titanium, titanium nitride, tantalum nitride, lanthanum nitride, titanium silicon nitride, tantalum silicon nitride, lanthanum oxide, aluminum oxide, and/or scandium oxide.

4. The gate structure according to claim 1, further comprising:
a second conductive pattern on the first conductive pattern,
wherein the second conductive pattern includes doped polysilicon.

5. The gate structure according to claim 4, further comprising:
a gate mask on the second conductive pattern,
wherein the gate insulation pattern contacts a sidewall of the second conductive pattern and a sidewall of the gate mask.

6. The gate structure according to claim 1, further comprising:
a second conductive pattern on the first conductive pattern,
wherein the second conductive pattern includes a third material, and
wherein the third material has a third work function that is lower than the second work function.

7. The gate structure according to claim 1, further comprising:
a second conductive pattern on the first conductive pattern; and
a second seed pattern on a lower surface and a sidewall of the second conductive pattern,
wherein the second seed pattern is in contact with an upper surface of the first conductive pattern,
wherein the second conductive pattern includes a third material,
wherein the second seed pattern includes a fourth material,
wherein the third material has a third work function, and
wherein the fourth material has a fourth work function that is lower than the third work function.

8. The gate structure according to claim 7, wherein the third material is same as the second material, and
wherein the fourth material is same as the first material.

9. A gate structure comprising:
a first conductive pattern;
a first seed pattern on a lower surface and a portion of a sidewall of the first conductive pattern, wherein the first seed pattern includes a first material, and the first conductive pattern includes a second material that is different from the first material;
a second conductive pattern that is in contact with an upper surface of the first conductive pattern and an uppermost surface of the first seed pattern; and
a gate insulation pattern that is in contact with a sidewall of the second conductive pattern and a sidewall of the first seed pattern,
wherein the first material has a first work function, and the second material has a second work function, and
wherein the first work function is lower than the second work function.

10. The gate structure according to claim 9, wherein the second conductive pattern includes doped polysilicon.

11. The gate structure according to claim 9, wherein the second conductive pattern includes a third material that has a third work function, and
wherein the third work function is lower than the second work function.

12. The gate structure according to claim 9, further comprising:
a gate mask on the second conductive pattern,
wherein the gate insulation pattern is in contact a sidewall of the gate mask.

13. The gate structure according to claim 9, wherein the second material includes molybdenum, and
wherein the first material includes tantalum, tantalum titanium, titanium nitride, tantalum nitride, lanthanum nitride, titanium silicon nitride, tantalum silicon nitride, lanthanum oxide, aluminum oxide, and/or scandium oxide.

14. A semiconductor device comprising:
an active pattern on a substrate;
a gate structure in an upper portion of the active pattern;
a bit line structure on a central portion of the active pattern;
a contact plug structure on each of opposite edge portions of the active pattern in a horizontal direction that is parallel with an upper surface of the substrate; and
a capacitor on the contact plug structure,
wherein the gate structure includes:
a first conductive pattern;
a first seed pattern on a lower surface and a first portion of a sidewall of the first conductive pattern, wherein the first seed pattern includes a first material, and the first conductive pattern includes a second material that is different from the first material; and
a gate insulation pattern that is in contact with a second portion of the sidewall of the first conductive pattern and the first seed pattern,
wherein the first material has a first work function, and the second material has a second work function, and
wherein the first work function is lower than the second work function.

15. The gate structure according to claim 14, wherein a lower surface of the first seed pattern is aligned with the second portion of the sidewall of the first conductive pattern.

16. The gate structure according to claim 14, wherein the second material includes molybdenum, and
wherein the first material includes tantalum, tantalum titanium, titanium nitride, tantalum nitride, lanthanum nitride, titanium silicon nitride, tantalum silicon nitride, lanthanum oxide, aluminum oxide, and/or scandium oxide.

17. The gate structure according to claim 14, further comprising:
a second conductive pattern on the first conductive pattern,
wherein the second conductive pattern includes doped polysilicon.

18. The gate structure according to claim 17, further comprising:
a gate mask on the second conductive pattern,
wherein the gate insulation pattern is in contact with a sidewall of the second conductive pattern and a sidewall of the gate mask.

19. The gate structure according to claim 14, further comprising:
a second conductive pattern on the first conductive pattern,
wherein the second conductive pattern includes a third material,
wherein the third material has a third work function that is lower than the second work function.

20. The gate structure according to claim 14, further comprising:
a second conductive pattern on the first conductive pattern; and
a second seed pattern on a lower surface and a sidewall of the second conductive pattern,
wherein the second seed pattern is in contact with an upper surface of the first conductive pattern,
wherein the second conductive pattern includes a third material,
wherein the second seed pattern includes a fourth material,
wherein the third material has a third work function, and
wherein the fourth material has a fourth work function that is lower than the third work function.
